(19) United States
(12) Patent Application Publication
(10) Pub. No.: US 2026/0362976 A1
(43) Pub. Date: Nov. 12, 2026

(54) THERMOELECTRIC CONVERSION DEVICE, POWER SUPPLY SYSTEM, AND POWER SUPPLY METHOD

(71) Applicant: TOPOLOGIC INC., Tokyo (JP)

(72) Inventor: Arata TAKAHASHI, Tokyo (JP)

(21) Appl. No.: 19/474,890

(22) PCT Filed: Apr. 22, 2024
(86) PCT No.: PCT/JP2024/015693

§ 371 Date: Oct. 13, 2025

(30) Foreign Application Priority Data
Apr. 21, 2023 (JP) 2023-069932

(51) Int. Cl. H10N 10/17; H10N 15/00

(52) U.S. Cl. CPC H10N 10/17; H10N 15/00

(57) ABSTRACT

A thermoelectric conversion device comprises at least one thermoelectric conversion element, a first electrode, and a second electrode. The thermoelectric conversion element is configured to generate a thermoelectromotive force induced by a temperature gradient along a first direction. The thermoelectromotive force includes Seebeck electromotive force generated along the first direction by the Seebeck effect based on the temperature gradient, and Nernst electromotive force generated so as to have a component along a second direction perpendicular to the first direction by the anomalous Nernst effect based on the temperature gradient. The first electrode is connected to a first connection region of the thermoelectric conversion element. The second electrode is connected to a second connection region of the thermoelectric conversion element. The first connection region and the second connection region are separated from each other in the first direction, and are separated from each other in the second direction.

### CROSS REFERENCE TO RELATED APPLICATIONS

This application is a 371 U.S. National Phase of International Application No. PCT/JP2024/015693, filed on Apr. 22, 2024, which claims priority to Japanese Patent Application No. 2023-069932, filed on Apr. 21, 2023. The entire disclosures of the above applications are incorporated herein by reference.

### BACKGROUND

### Technical Field

The present disclosure relates to a thermoelectric conversion device, a power supply system, and a power supply method.

### Related Art

JP 2023-083615 A (Patent Document 1) discloses a thermoelectric conversion element that produces a larger anomalous Nernst effect than conventional ones, as well as a thermoelectric conversion device including such a thermoelectric conversion element.

The thermoelectric conversion element is made of a Weyl metal and generates an electromotive force through the anomalous Nernst effect. The density of states of the ferromagnetic material exhibits energy dependence with an extremum near the Fermi energy E_{F}. The thermoelectric coefficient −α_{yx}, which determines the electromotive force, exhibits temperature (T) dependence proportional to −T log T. When a heat flow Q (−∇T) flows in the +x direction to the thermoelectric conversion element, a temperature difference occurs in the +x direction. As a result, the thermoelectric conversion element generates a voltage V (−M×∇T) in the y direction, which is orthogonal to both the direction of the heat flow Q (+x direction) and the direction of the magnetization M (+z direction), due to the anomalous Nernst effect.

However, the electromotive force based on the anomalous Nernst effect may be smaller than that based on the Seebeck effect. Therefore, there is still room for improvement in the technology for implementing a thermoelectric conversion device utilizing such an anomalous Nernst effect.

### SUMMARY

According to an aspect of the present disclosure, a thermoelectric conversion device is provided. This thermoelectric conversion device includes at least one thermoelectric conversion element, a first electrode, and a second electrode. The thermoelectric conversion element is configured to generate a thermoelectromotive force due to a temperature gradient along a first direction. The thermoelectromotive force includes a Seebeck electromotive force generated along the first direction by a Seebeck effect based on the temperature gradient, and a Nernst electromotive force generated by an anomalous Nernst effect based on the temperature gradient so as to have a component along a second direction perpendicular to the first direction. The first electrode is connected to a first connection region of the thermoelectric conversion element. The second electrode is connected to a second connection region of the thermoelectric conversion element. The first connection region and the second connection region are spaced apart in the first direction and also are spaced apart in the second direction.

### BRIEF DESCRIPTION OF THE DRAWINGS

FIG. 1 is a diagram showing an example of a power supply system 1 using a thermoelectric conversion device.

FIG. 2 is a plan view of a thermoelectric conversion device 2 shown in FIG. 1 as viewed from a width direction D3.

FIG. 3 is a diagram for explaining an example of a power supply method using the power supply system 1 shown in FIG. 2.

FIG. 4 is a diagram showing another example of the thermoelectric conversion device 2.

FIG. 5 is a diagram showing another example of the thermoelectric conversion device 2.

FIG. 6 is a diagram showing an example of the power supply system 1.

FIG. 7 is a plan view of a part of the power supply system 1 shown in FIG. 6, as viewed from the width direction D3.

FIG. 8 is a diagram showing an example of the thermoelectric conversion device 2 including at least a first thermoelectric conversion element 3a and a third thermoelectric conversion element 3c.

FIG. 9 is a diagram showing an example of the thermoelectric conversion device 2 including a plurality of thermoelectric conversion elements 3.

### DETAILED DESCRIPTION

Hereinafter, a suitable embodiment of the present disclosure will be described in detail with reference to the accompanying drawings. In this specification and the drawings, components having substantially identical functional configurations are indicated with the same reference signs and duplicate explanations are omitted.

A program for implementing a software described in one embodiment may be provided as a non-transitory computer-readable storage medium, may be made available for download from an external server, or may be provided in such a manner that the program can be activated on an external computer to implement functions thereof on a client terminal (so-called cloud computing).

In various types of information processing according to one embodiment, an input and an output corresponding to the input can be realized. Here, as long as an output is obtained as a result of the input, the form of information referred to in such information processing (hereinafter referred to as reference information) is not limited. The reference information may be, for example, rule-based information such as a database, a look-up table, a predefined function (including a decision formula such as a regression equation constructed by statistical methods), may be a trained model in which the correlation between an input and an output has been learned in advance, or may be a large-scale language model capable of outputting a desired result by inputting a prompt.

In one embodiment, the term “unit” may also include, for example, a combination of hardware resources implemented by a circuit in a broad sense, and information processing performed by software that may be specifically implemented by such hardware resources. Furthermore, various kinds of information are handled in one embodiment, and such information may be represented by, for example, physical values of signal values representing voltage and current, high and low signal values as a set of binary bits consisting of 0 or 1, or quantum superposition (so-called qubits), and communication and computation may be executed on a circuit in a broad sense.

Furthermore, the term “circuit in a broad sense” refers to a circuit that is implemented by appropriately combining at least one or more of a circuit, circuitry, a processor, memory, and the like. Additionally, the processor may be a general-purpose processor or a dedicated circuit. In other words, the term “circuit in a broad sense” includes an application specific integrated circuit (ASIC), a programmable logic device (e.g., a simple programmable logic device (SPLD), a complex programmable logic device (CPLD), a field programmable gate array (FPGA)), and the like.

### 1. Overview

For example, in a conventional power generation device using a thermoelectric conversion element, the Seebeck effect is generally utilized. However, the thermoelectric conversion element using the Seebeck effect tend to trap heat, making it difficult for heat to be discharged from areas where it should be discharged. As a result, the temperature difference along the heat flow direction tends to decrease, thereby leading to a reduction in power generation efficiency.

On the other hand, in an element using a transverse thermoelectric conversion effect, such as the anomalous Nernst effect which has attracted attention in recent years, an electromotive force is generated in the planar direction of the element, thereby allowing the thickness to be reduced. This results in favorable heat dissipation. However, sufficient energy for power generation and the like is difficult to obtain.

Accordingly, in a device according to the present embodiment, a system using the device, and a method using the device or the system, for example, by providing, in a predetermined configuration, an element made of a material having relatively high thermal conductivity capable of sufficiently producing both the anomalous Nernst effect and the Seebeck effect, it is possible to obtain a voltage generated by both the Seebeck effect and the anomalous Nernst effect. This makes it possible to enhance the thermoelectric conversion efficiency and achieve thermoelectric power generation with higher output.

In terms of responsiveness, it is preferable that the thermoelectric conversion device (an example of the device) according to the present embodiment is a thin-film type thermoelectric conversion device based on the anomalous Nernst effect. The element (thermoelectric conversion element) of the thermoelectric conversion device may be made of an alloy or compound that exhibits the anomalous Nernst effect. The element may be made of, for example, a topological ferromagnetic material or a topological antiferromagnetic material, known as a Weyl semimetal, or it may be made of a ferrimagnetic material, or it may be a combination of these. The topological ferromagnetic material may be a metal with a Co₂TX composition, such as Co₂MnGa (where X is any one of Si, Ge, Sn, Al, and Ga), or an alloy of a known topological ferromagnetic material, such as a metal with a composition formula represented by Fe₃X (where X is a stoichiometric composition that is a typical element or transition element such as Al or Ga). In addition, the topological antiferromagnetic material may be a known topological antiferromagnetic material such as Mn₃X (where X is one or more elements selected from Sn, Ge, Ga, Pt, Ir, and Rh, or a compound thereof). The compound that constitutes the element may be, for example, an alloy containing a transition metal, and the alloy may be a compound having a crystal structure with kagome lattice planes formed by the transition metal, and may exhibit the anomalous Nernst effect. The ferrimagnetic material is also not particularly limited, as long as it exhibits the anomalous Nernst effect. The structure of the element is not particularly limited, and any known structures can be used. In addition, the element according to the present embodiment may be provided by sputtering, vapor deposition, MBE, plating, granulation, 3D printing, melting, sintering, printing, bonding, etc.

### 2. Example of Thermoelectric Conversion Device And Power Supply System

### 2.1. Example of Overall Configuration

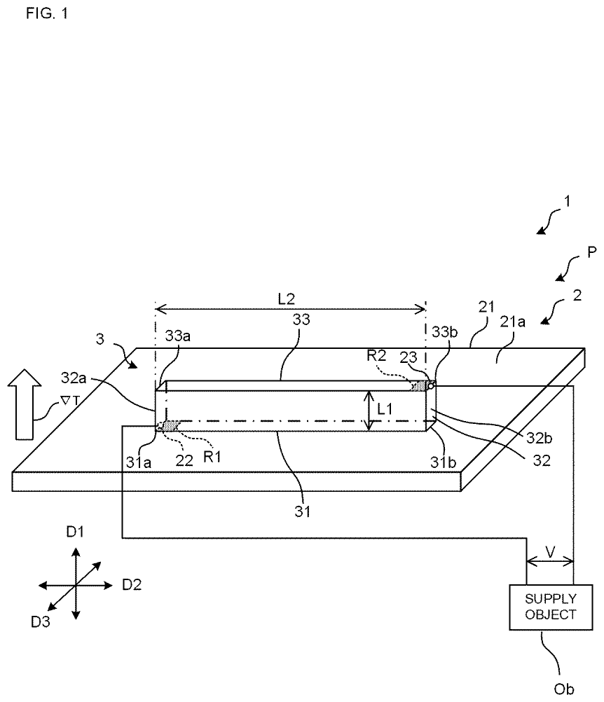

Next, a configuration example of a power supply system 1, which is an example of the above-mentioned thermoelectric conversion device and a system using the thermoelectric conversion device, will be described. FIG. 1 is a diagram showing an example of a power supply system 1 using a thermoelectric conversion device.

As shown in FIG. 1, the power supply system 1 includes a supply object Ob and a power supply part P. The supply object Ob is configured to be supplied with electric power. The specific aspect of the supply object Ob is not particularly limited, and may include, for example, any object that functions based on electric power, such as a light-emitting device such as lighting or a display, an acoustic device such as a microphone or a speaker, a detection device such as a sensor, a driving device such as a motor or an actuator, a control device such as a microcomputer, a device capable of storing electric power such as a storage battery, or the like.

The power supply part P is configured to supply electric power to the supply object Ob. The power supply part P includes a thermoelectric conversion device 2, and is configured to output electric power to a supply object based on the thermoelectromotive force V output from the thermoelectric conversion device 2. The power supply part P may include a power converter (not shown) capable of performing power conversion for the thermoelectromotive force V output from the thermoelectric conversion device 2. When the thermoelectromotive force V is output as a direct current signal, the power converter may be implemented as a DC/DC converter, a DC/AC inverter, a signal amplifier, or the like. When the thermoelectromotive force V is output as an alternating current signal, the power converter may be implemented as an AC/AC converter, an AC/DC converter, a comparator, or the like.

The thermoelectric conversion device 2 is a device configured to output a thermoelectromotive force based on a temperature gradient ∇T. The thermoelectric conversion device 2 includes at least one thermoelectric conversion element 3, a substrate 21, a first electrode 22, and a second electrode 23. In the present embodiment, the thermoelectric conversion device 2 includes one thermoelectric conversion element 3 as the at least one thermoelectric conversion element 3.

The thermoelectric conversion element 3 is configured to generate a thermoelectromotive force V due to a temperature gradient along the gradient direction D1. The thermoelectromotive force V includes a Seebeck electromotive force V1 and a Nernst electromotive force V2. The Seebeck electromotive force V1 is generated along the gradient direction D1 by the Seebeck effect based on the temperature gradient ∇T. The Nernst electromotive force V2 is generated by the anomalous Nernst effect based on the temperature gradient ∇T so as to have a component along the longitudinal direction D2 perpendicular to the gradient direction D1.

The substrate 21 includes a placement surface 21a. The placement surface 21a is a surface defined by a normal direction that is along the gradient direction D1, and in the present embodiment, it is a flat surface. Note that the placement surface 21a may include a curved surface as long as the thermoelectric conversion element 3 described later can be placed thereon. The gradient direction is an example of a first direction and is the direction that defines the temperature gradient to be introduced into the thermoelectric conversion element 3 described later. Here, the placement surface 21a is configured so that the normal direction of the placement surface 21a coincides with the gradient direction D1. Note that the substrate 21 may be a rigid substrate such as a printed circuit board, or may be configured to be deformable such as a flexible substrate. In addition, the in-plane direction of the placement surface 21a is defined by the longitudinal direction D2 and the width direction D3 which are perpendicular to the gradient direction D1. Here, the longitudinal direction D2 and the width direction D3 are also orthogonal to each other.

The first electrode 22 and the second electrode 23 are terminals for outputting the above-mentioned thermoelectromotive force V generated from the thermoelectric conversion element 3 to the outside, and are electrically connected to the thermoelectric conversion element 3. The following describes a specific example of the relationship between the thermoelectric conversion element 3, the first electrode 22, and the second electrode 23.

The thermoelectric conversion element 3 is configured to generate the Nernst electromotive force V2 that is along the longitudinal direction D2 relative to the temperature gradient ∇T that is along the gradient direction D1 by being magnetized along the width direction D3. The thermoelectric conversion element 3 is configured to extend along the longitudinal direction D2. With such a configuration, the Nernst effect generated from the thermoelectric conversion element 3 can be increased, thereby further increasing the thermoelectromotive force output from the thermoelectric conversion device 2. Specifically, the length L2 of the thermoelectric conversion element 3 in the longitudinal direction D2 is longer than the length L1 of the thermoelectric conversion element 3 in the gradient direction D1. With such a configuration, the contribution of the Nernst electromotive force V2 included in the thermoelectromotive force becomes greater, and thus the response speed to the generation or change of the temperature gradient in the thermoelectric conversion device 2 can be increased. Hereinafter, for convenience of explanation, the length L1 of the thermoelectric conversion element 3 in the gradient direction D1 is referred to as the thickness L1, and the length L2 of the thermoelectric conversion element 3 in the longitudinal direction D2 is simply referred to as the length L2. The specific shape of the thermoelectric conversion element 3 may be any desired shape; however, in the present embodiment, it is formed in a rectangular parallelepiped shape extending along the longitudinal direction D2. The L1/L2 may be any length, but is preferably 1 or less, and specifically, may be, for example, 0.001, 0.005, 0.01, 0.05, 0.1, 0.5, or 1, and may also be within the range between any two of the exemplified values here.

The thermoelectric conversion element 3 includes a lower surface 31 as an example of a first surface, a peripheral surface 32, and an upper surface 33 as an example of a second surface.

The lower surface 31 is a surface facing the placement surface 21a in the gradient direction D1, and is defined, for example, so as to be in contact with the placement surface 21a. The lower surface 31 may have any shape as long as it matches the placement surface 21a; however, in the present embodiment, the lower surface 31 is defined as a rectangular planar shape having a normal extending in the gradient direction D1, two short sides spaced apart in the longitudinal direction D2, and two long sides spaced apart in the width direction D3. The lower surface 31 includes a first end 31a and a second end 31b. The first end 31a and the second end 31b are different ends of the lower surface 31 in the longitudinal direction D2. In the present embodiment, the first end 31a and the second end 31b are positioned apart from each other in the longitudinal direction D2 and are defined by the two short sides of the lower surface 31. The distance between the first end 31a and the second end 31b is equal to the above-mentioned length L2.

In the present embodiment, the lower surface 31 includes a first connection region R1. The first connection region R1 is a region electrically and physically connected to the first electrode 22, and is defined, for example, so as to include the first end 31a. The first connection region R1 is provided with a conductor, such as a gold thin film, for making contact between the lower surface 31 and the first electrode 22. The first electrode 22 is connected to the first connection region R1 of the thermoelectric conversion element 3.

The peripheral surface 32 is connected to the outer peripheral edge of the lower surface 31 including the first end 31a and the second end 31b, and extends from the outer peripheral edge along the gradient direction D1 so as to move away from the placement surface 21a of the substrate 21. In other words, one of the two ends of the peripheral surface 32 in the gradient direction D1 is connected to the lower surface 31. In the present embodiment, the peripheral surface 32 is defined by four surfaces that are continuous in the circumferential direction of the gradient direction D1, corresponding to the rectangular shape of the lower surface 31. For example, the peripheral surface 32 includes a first side surface 32a and a second side surface 32b. The first side surface 32a is a portion of the peripheral surface 32 that extends from the first end 31a of the lower surface 31. The second side surface 32b is a portion of the peripheral surface 32 that extends from the second end 31b of the lower surface 31. The first side surface 32a and the second side surface 32b are positioned apart from each other in the longitudinal direction D2. The shapes of the first side surface 32a and the second side surface 32b may each be any shape; for example, may be planar, and specifically rectangular.

The upper surface 33 is positioned opposite to the lower surface 31 in the gradient direction D1. For example, the upper surface 33 is connected, of the two ends of the peripheral surface 32 in the gradient direction D1, to an end that is different from the one connected to the lower surface 31. The upper surface 33 may have any shape as long as it matches the peripheral surface 32. In the present embodiment, similar to the lower surface 31, the upper surface 33 is defined as a rectangular planar shape having a normal extending in the gradient direction D1, two short sides spaced apart in the longitudinal direction D2, and two long sides spaced apart in the width direction D3. The upper surface 33 includes a first end 33a and a second end 33b.

The first end 33a and the second end 33b are different ends of the upper surface 33 in the longitudinal direction D2. In the present embodiment, the first end 33a and the second end 33b are positioned apart from each other in the longitudinal direction D2 and are defined by the two short sides of the upper surface 33. The distance between the first end 33a and the second end 33b is equal to the above-mentioned length L2. The first end 33a of the upper surface 33 is positioned in the gradient direction D1 from the first end 31a of the lower surface 31. The second end 33b of the upper surface 33 is positioned in the gradient direction D1 from the second end 31b of the lower surface 31. Accordingly, the first end 31a and the second end 33b are positioned apart from each other in both the gradient direction D1 and the longitudinal direction D2. In the present embodiment, the distance between the lower surface 31 and the upper surface 33 in the gradient direction D1 is equal to the above-mentioned thickness L1.

In the present embodiment, the upper surface 33 further includes a second connection region R2. With such a configuration, the component of the Seebeck electromotive force V1 included in the thermoelectromotive force output from the first electrode 22 and the second electrode 23 can be increased. The second connection region R2 is a region electrically and physically connected to the second electrode 23, and is defined, for example, so as to include the second end 33b. The second connection region R2 is provided with a conductor, such as a gold thin film, for making contact between the upper surface 33 and the second electrode 23. The distance d1 between the first connection region R1 and the placement surface 21a in the gradient direction D1 is shorter than the distance d2 between the second connection region R2 and the placement surface 21a in the gradient direction D1. In other words, of the two regions to which the two electrodes 22 and 23 are connected, the region having a shorter distance from the placement surface 21a is the first connection region R1, and the region having a longer distance from the placement surface 21a is the second connection region R2. The second electrode 23 is connected to the second connection region R2 of the thermoelectric conversion element 3. In the present embodiment, the first connection region R1 includes the first end 31a, the second connection region R2 includes the second end 33b, and the first end 31a and the second end 33b are spaced apart in the gradient direction D1 and also spaced apart in the longitudinal direction D2, so that the first connection region R1 and the second connection region R2 are spaced apart in the gradient direction D1 and also spaced apart in the longitudinal direction D2. In addition, since the first connection region R1 includes the first end 31a and the second connection region R2 includes the second end 33b, the first connection region R1 and the second connection region R2 are each arranged at both ends of the thermoelectric conversion element 3 in the longitudinal direction D2. With such a configuration, the component of the Nernst electromotive force V2 included in the thermoelectromotive force output from the first electrode 22 and the second electrode 23 can be increased.

According to the above configuration, since the first connection region R1 and the second connection region R2 are spaced apart in the gradient direction D1, the first electrode 22 and the second electrode 23 can output the Seebeck electromotive force V1 generated along the gradient direction D1. Furthermore, since the first connection region R1 and the second connection region R2 are spaced apart in the longitudinal direction D2, the first electrode 22 and the second electrode 23 can also output the Nernst electromotive force V2 generated along the longitudinal direction D2. As a result, the first electrode 22 and the second electrode 23 can output, as the thermoelectromotive force, an electromotive force in which the Seebeck electromotive force V1 and the Nernst electromotive force V2 are superimposed on each other. This makes it possible to provide a thermoelectric conversion system capable of outputting a larger electromotive force compared with the case where only one of the electromotive forces is output, for example.

In other words, the thermoelectric conversion element 3 has an elongated shape and is provided on the substrate 21 (for example, on the placement surface 21a) so as to lie flat along the planar direction of the substrate 21 (for example, in the direction defined by the longitudinal direction D2 and the width direction D3, in the present embodiment, the longitudinal direction D2). At one end of the thermoelectric conversion element 3 in the longitudinal direction D2, the first electrode 22 is provided at an end in the vertical direction (an example of the gradient direction D1) (e.g., the first end 31a of the lower surface 31), and at the other end in the longitudinal direction D2 (e.g., the second end 31b of the lower surface 31), the second electrode 23 is provided at the end opposite to the end where the first electrode 22 is provided, in the vertical direction (e.g., the second end 33b).

In such an arrangement, for example, when a heat flow passes upward from the substrate 21 side (lower side), the temperature on the lower side becomes higher than that on the upper side. In this case, the Seebeck effect occurs in the vertical direction in the thermoelectric conversion element 3, and the anomalous Nernst effect occurs in the planar direction (in this case, the magnetization direction of the thermoelectric conversion element is perpendicular to the longitudinal direction D2 along the plane). The voltage V generated at this time is the sum of V1 (the voltage generated by the Seebeck effect) and V2 (the voltage generated by the anomalous Nernst effect). By arranging the thermoelectric conversion element 3 and the electrodes 22 and 23 in this way, the thermoelectric conversion efficiency can be increased, and a greater voltage can be extracted.

### 2.2. Relationship Between Connection Regions R1, R2 and Thermoelectromotive Force V

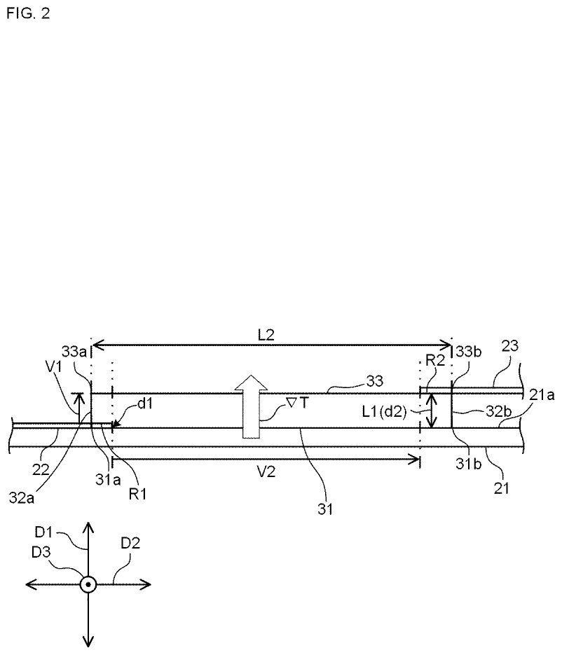

Next, the relationship between the connection regions R1 and R2 and thermoelectromotive force V in the above-mentioned thermoelectric conversion device 2 will be described in more detail. FIG. 2 is a plan view of the thermoelectric conversion device 2 shown in FIG. 1 as viewed from the width direction D3. As shown in FIG. 2, when a temperature gradient ∇T along the gradient direction D1 is introduced into the thermoelectric conversion element 3, the Seebeck electromotive force V1 along the gradient direction D1 and the Nernst electromotive force V2 along the longitudinal direction D2 are induced in the thermoelectric conversion element 3. Here, as one example, a case will be described in which the temperature T1 of the lower surface 31 is higher than the temperature T2 of the upper surface 33. For convenience of explanation, it is assumed that the temperature of the lower surface 31 is uniformly T1, the temperature of the upper surface 33 is uniformly T2, and there is no temperature gradient within the plane.

In this case, a temperature gradient ∇T is generated in the thermoelectric conversion element 3 between the lower surface 31 and the upper surface 33, and a heat flow occurs based on the temperature gradient ∇T. In addition, in the thermoelectric conversion element 3, the Nernst electromotive force V2 is induced by the heat flow associated with the temperature gradient ∇T. Inside the thermoelectric conversion element 3, an internal electric field along the gradient direction D1 due to the Seebeck electromotive force V1 and an internal electric field along the longitudinal direction D2 due to the Nernst electromotive force V2 are generated, respectively. As a result, ideally, a potential difference corresponding to the Seebeck electromotive force V1 is generated between the first end 31a and the first end 33a, and/or between the second end 31b and the second end 33b, and a potential difference corresponding to the Nernst electromotive force V2 is generated between the first end 31a and the second end 31b and/or between the first end 33a and the second end 33b. Consequently, the potential difference between the first end 31a and the second end 33b is ideally V1+V2. Here, since the first connection region R1 and the second connection region R2 are spaced apart in the gradient direction D1, a potential difference based on the Seebeck electromotive force V1 is generated between the first electrode 22 and the second electrode 23. Furthermore, since the first connection region R1 and the second connection region R2 are spaced apart in the longitudinal direction D2, a potential difference based on Nernst electromotive force V2 is generated between the first electrode 22 and the second electrode 23. This increases the thermoelectromotive force of the thermoelectric conversion element 3 obtained from the same temperature gradient ∇T, thereby improving the thermoelectric conversion efficiency. As a result, for example, it is possible to improve the efficiency of the power supply to the supply object Ob using the thermoelectric conversion device 2. From another perspective, when detecting a heat flow using the thermoelectric conversion device 2, it is possible to obtain a larger signal.

### 2.3. Example of Power Supply Method

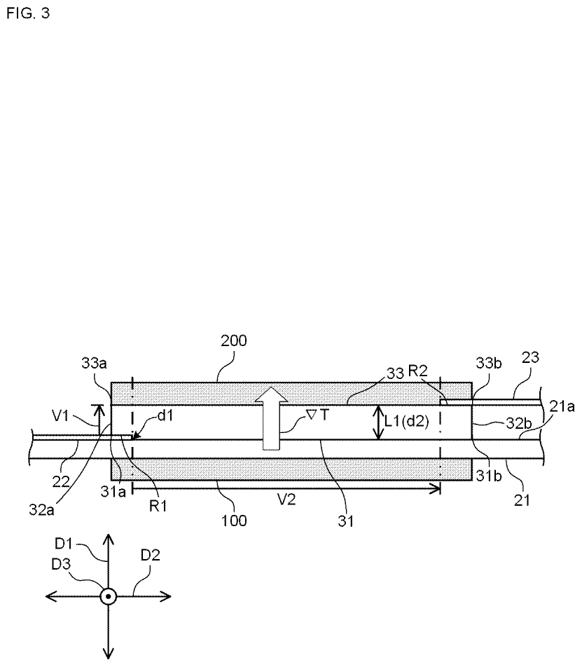

Next, an example of a power supply method using the above-mentioned power supply system 1 will be described. FIG. 3 is a diagram for explaining an example of a power supply method using the power supply system 1 shown in FIG. 2.

The power supply system 1 introduces a temperature difference between the lower surface 31 and the upper surface 33 of the thermoelectric conversion element 3 by connecting temperature regulation sections 100 and 200 to the thermoelectric conversion device 2. The temperature regulation section 100 is connected to the lower surface 31 of the thermoelectric conversion element 3 via the substrate 21. The temperature regulation section 200 is connected to the upper surface 33 of the thermoelectric conversion element 3. Various layers, such as an insulating layer, may be interposed between the temperature regulation section 200 and the upper surface 33. The temperature regulation sections 100 and 200 may be heating elements for heating the lower surface 31 or the upper surface 33, or coolers for cooling the lower surface 31 or the upper surface 33. Thus, the thermoelectromotive force V including the Seebeck electromotive force V1 and the Nernst electromotive force V2 is generated between the first electrode 22 and the second electrode 23. Introducing a temperature difference between the lower surface 31 and the upper surface 33 is one example of introducing a temperature gradient ∇T along the gradient direction D1 into the thermoelectric conversion device 2. In this case, the power supply system 1 introduces the temperature gradient by attaching the thermoelectric conversion device 2 to the power supply object. For example, at least one of the temperature regulation sections 100 and 200 may serve as the supply object Ob. With such a configuration, the heat generated when supplying power to the power supply object, or the heat generated when the supply object is driven by the supplied power, can be used to introduce a temperature gradient into the thermoelectric conversion device 2. This makes it possible to reduce heat energy loss in the supply object.

Next, the power supply system 1 supplies to the power supply object Ob an electric signal based on the thermoelectromotive force V generated from the thermoelectric conversion device 2 based on the temperature gradient ∇T. The electric signal may be any of voltage, current, or power. This enables the power supply system 1 to drive the supply object Ob. Note that the above-mentioned power supply method may be used with various alternative examples of the power supply system 1 described below.

### 2.4. Another Example of Thermoelectric Conversion Device 2

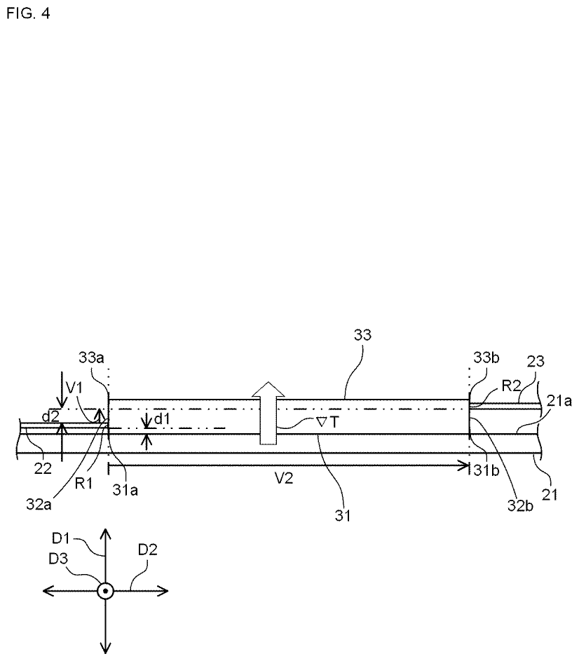

The thermoelectric conversion device 2 described above is configured such that the first connection region R1 is included in the first connection region R1 that is as a first surface, and the second connection region R2 is included in the second connection region R2 that is as a second surface. However, the present disclosure is not limited thereto. The positions of the first connection region R1 and the second connection region R2 are any positions as long as the first connection region R1 and the second connection region R2 are spaced apart in the gradient direction D1 and also spaced apart in the longitudinal direction D2. FIG. 4 is a diagram showing another example of the thermoelectric conversion device 2. As shown in FIG. 4, the first connection region R1 may be included in the first side surface 32a. Furthermore, the second connection region R2 may be included in the second side surface 32b. In other words, the first electrode 22 and the second electrode 23 may be connected to the peripheral surface 32 of the thermoelectric conversion element 3.

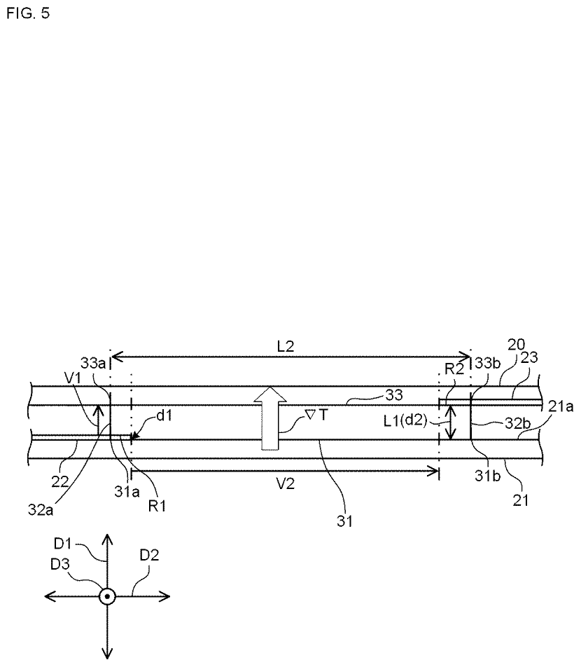

In addition, the thermoelectric conversion device 2 may also include a support substrate 20 in addition to or in place of the substrate 21. FIG. 5 is a diagram showing another example of the thermoelectric conversion device 2. As shown in FIG. 5, the support substrate 20 is arranged so as to face the upper surface 33 in the gradient direction D1 and is arranged so as to support the upper surface 33 and the second electrode 23 in the gradient direction D1. When the thermoelectric conversion device 2 includes both the substrate 21 and the support substrate 20, the thermoelectric conversion element 3 is sandwiched in the gradient direction D1 between the substrate 21 and the support substrate 20. This makes it possible to enhance the robustness of the thermoelectric conversion device 2. Furthermore, at least a part of the first electrode 22 and the second electrode 23 may be incorporated on the surface of or inside the substrate 21 and the support substrate 20, respectively. In this case, the thermoelectric conversion device 2 can be implemented by a relatively simple method such as depositing by sputtering or the like the thermoelectric conversion element 3 in a predetermined shape on the substrate 21 or the support substrate 20 on which the first electrode 22 and the second electrode 23 have been patterned in advance.

### 3. Example of Power Supply System Including a Plurality of Thermoelectric Conversion Devices

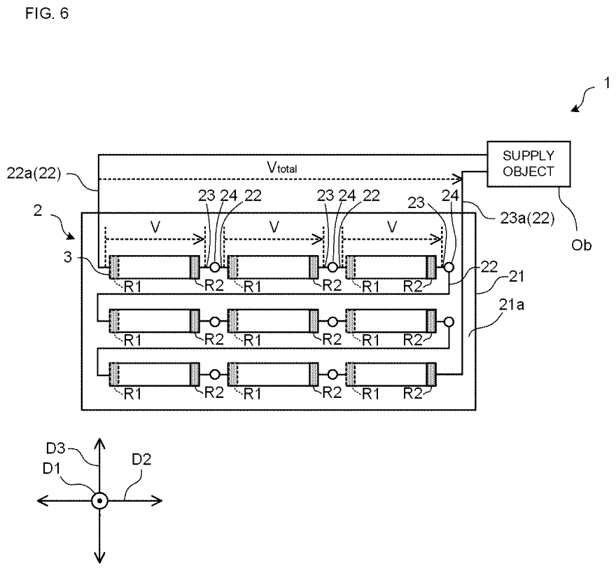

Next, an example of the power supply system 1 including a plurality of thermoelectric conversion elements 3 will be described. Hereinafter, for convenience of explanation, the embodiment of the power supply system 1 described in Section 2 is referred to as the first embodiment, and the embodiment of the power supply system 1 described in this section is referred to as the second embodiment. In the second embodiment of the power supply system 1 described in this section, configurations that are common to the first embodiment of the power supply system 1 described above are omitted by using the same reference numerals. FIG. 6 is a diagram showing an example of the power supply system 1.

As shown in FIG. 6, the power supply system 1 includes the supply object Ob and the thermoelectric conversion device 2. The thermoelectric conversion device 2 includes a substrate 21, a plurality of thermoelectric conversion elements 3 as at least one thermoelectric conversion element, a plurality of first electrodes 22, a plurality of second electrodes 23, and a plurality of connecting members 24. Here, for convenience of explanation, the plurality of thermoelectric conversion elements 3 are configured to have structures and characteristics similar to each other; however, each of the thermoelectric conversion elements 3 may have different structures or characteristics.

Each of the plurality of thermoelectric conversion elements 3 is arranged on the placement surface 21a of the substrate 21. Each of the plurality of thermoelectric conversion elements 3 extends along the gradient direction D1. At least two (three in this case) of the plurality of thermoelectric conversion elements 3 are arranged along the gradient direction D1. As a result, the plurality of thermoelectric conversion elements 3 form a plurality of rows along the gradient direction D1. In the present embodiment, the plurality of thermoelectric conversion elements 3 are further arranged so as to form a plurality of columns along the width direction D3. Each of the plurality of first electrodes 22 is connected to a respective first connection region R1 of the plurality of thermoelectric conversion elements 3, and each of the plurality of second electrodes 23 is connected to a respective second connection region R2 of the plurality of thermoelectric conversion elements 3.

The connecting member 24 is a conductor configured to connect the first electrodes 22 and the second electrodes 23 of two adjacent thermoelectric conversion elements 3. This allows the two thermoelectric conversion elements 3 to be connected in series via the first electrode 22, the connecting member 24, and the second electrode 23. Hereinafter, for convenience of explanation, among the thermoelectric conversion elements 3 connected in series on the circuit, the thermoelectric conversion elements 3 that are directly connected via the connecting member 24 are referred to as thermoelectric conversion elements 3 adjacent to each other on the circuit. Each of the plurality of thermoelectric conversion elements 3 arranged on the substrate 21 generates a thermoelectromotive force V when a similar temperature gradient ∇T is introduced. Since the plurality of thermoelectric conversion elements 3 are connected in series via the first electrode 22, the connecting member 24, and the second electrode 23, the thermoelectromotive forces V generated by each thermoelectric conversion element 3 are summed and output as an output electromotive force Vₜₒₜₐₗ from the first electrode 22 and the second electrode 23 used as the terminals. In FIG. 6, the first electrode 22 used as the terminal is denoted by 22a, and the second electrode 23 used as the terminal is denoted by 23a.

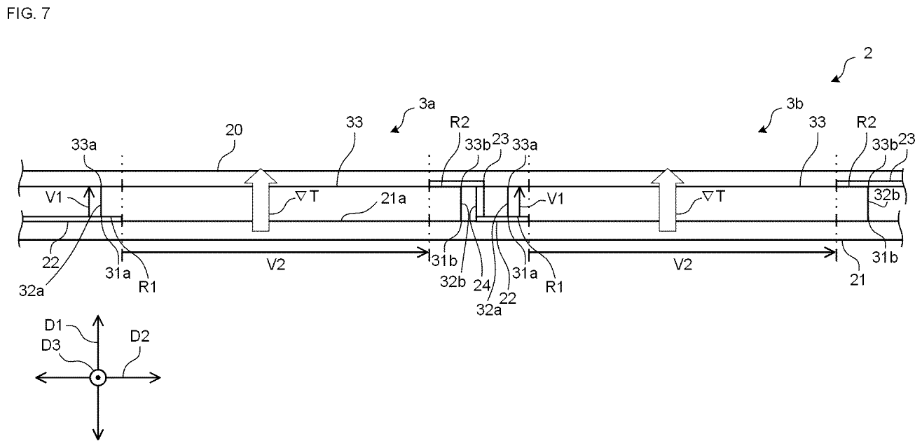

Next, an example of the connection configuration of two thermoelectric conversion elements 3 that are adjacent to each other on the circuit, among the plurality of thermoelectric conversion elements 3, is described. FIG. 7 is a plan view of a part of the power supply system 1 shown in FIG. 6, as viewed from the width direction D3. Here, for convenience of explanation, among the plurality of thermoelectric conversion elements 3, one of the two thermoelectric conversion elements 3 adjacent to each other on the circuit is referred to as the first thermoelectric conversion element 3a, and the other is referred to as the second thermoelectric conversion element 3b.

As shown in FIG. 7, similar to the case of the first embodiment, the distance d1 between the first connection region R1 of each of the plurality of thermoelectric conversion elements 3 and the placement surface 21a in the gradient direction D1 is shorter than the distance d2 between the second connection region R2 of each of the plurality of thermoelectric conversion elements 3 and the placement surface 21a in the gradient direction D1. In other words, of the two regions to which the two electrodes 22 and 23 are connected, the region having a shorter distance from the placement surface 21a is defined as the first connection region R1, and the region having a longer distance from the placement surface 21a is defined as the second connection region R2.

The second electrode 23 of the first thermoelectric conversion element 3a is connected to the second connection region R2 of the first thermoelectric conversion element 3a and extends from the second connection region R2 of the first thermoelectric conversion element 3a along the longitudinal direction D2 toward the second thermoelectric conversion element 3b.

The first electrode 22 of the second thermoelectric conversion element 3b is connected to the first connection region R1 of the second thermoelectric conversion element 3b, extends from the second connection region R2 of the second thermoelectric conversion element 3b along the longitudinal direction D2 toward the first thermoelectric conversion element 3a, and is configured to overlap with the second electrode 23 of the first thermoelectric conversion element 3a in the gradient direction D1.

The connecting member 24 extends in the gradient direction D1 so as to connect the second electrode 23 and the first electrode 22, which extend along the longitudinal direction D2 toward each other in this manner. The first thermoelectric conversion element 3a and the second thermoelectric conversion element 3b are connected in series by electrically connecting the connection region R2 of the first thermoelectric conversion element 3a and the connection region R1 of the second thermoelectric conversion element 3b. With configuration, the thermoelectromotive force generated by the first thermoelectric conversion element 3a and the thermoelectromotive force generated by the second thermoelectric conversion element 3b are added together in response to the temperature gradient in the same direction, and are output from the first electrode 22 and the second electrode 23, thereby further increasing the electromotive force output from the thermoelectric conversion device 2. In this case, the signs of the Seebeck coefficients (in other words, the diagonal components of the thermoelectric tensor) of the first thermoelectric conversion element 3a and the second thermoelectric conversion element 3b are the same, and the signs of the Nernst coefficients (in other words, the antisymmetric components of the thermoelectric tensor) of the first thermoelectric conversion element 3a and the second thermoelectric conversion element 3b may also be the same. As a result, a temperature gradient ∇T in the same direction via the substrate 21 induces a thermoelectromotive force in the same direction with each other, so that the output electromotive force Vₜₒₜₐₗ can be further increased.

In other words, when the heat source is located below (although a negative heat source may be located above), the heat flow occurs from the bottom to the top. As shown in FIG. 6 and FIG. 7, by connecting the thermoelectric conversion elements 3 described in the preceding section in series via a conductor, a greater voltage Vₜₒₜₐₗ can be extracted. Such thermoelectric conversion elements 3 may also be arranged in a two-dimensional array so as to be connected in series via conductors and wiring.

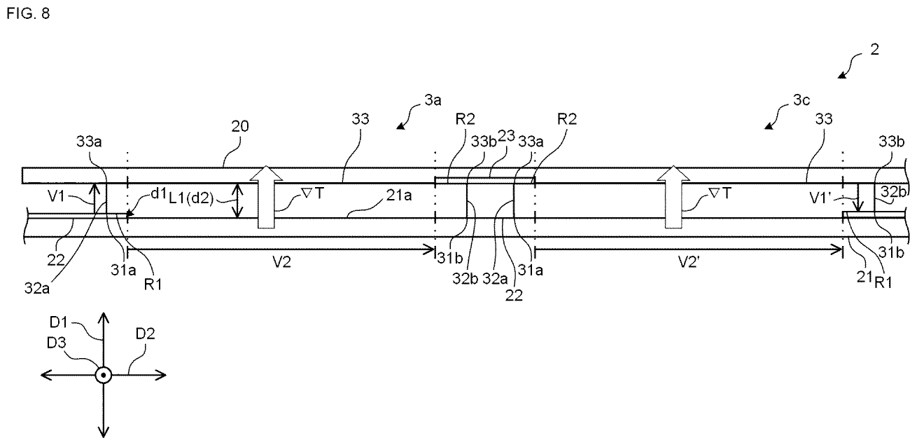

In addition, the plurality of thermoelectric conversion elements 3 may further include a third thermoelectric conversion element 3c in addition to at least the first thermoelectric conversion element 3a. FIG. 8 is a diagram showing an example of the thermoelectric conversion device 2 including at least the first thermoelectric conversion element 3a and the third thermoelectric conversion element 3c. In the present embodiment, the third thermoelectric conversion element 3c is connected in series between the first thermoelectric conversion element 3a and the second thermoelectric conversion element 3b. The third thermoelectric conversion element 3c has a Seebeck coefficient with a different sign from that of the first thermoelectric conversion element 3a and a Nernst coefficient with the same sign as that of the first thermoelectric conversion element 3a. In other words, the Nernst electromotive force V2′ of the third thermoelectric conversion element 3c generated due to the temperature gradient ∇T is configured to be generated in the same direction as the Nernst electromotive force V2 of the first thermoelectric conversion element 3a generated due to the temperature gradient ∇T. The Seebeck electromotive force V1′ of the third thermoelectric conversion element 3c generated due to the temperature gradient ∇T is configured to be generated in the opposite direction to the Seebeck electromotive force V1 of the first thermoelectric conversion element 3a generated due to the temperature gradient ∇T. The first connection region R1 of the third thermoelectric conversion element 3c is electrically connected to the second connection region R2 of the first thermoelectric conversion element 3a. The second connection region R2 of the third thermoelectric conversion element 3c is electrically connected to the first connection region R1 of the second thermoelectric conversion element 3b. With such a configuration, the third thermoelectric conversion element 3c can be incorporated between the first thermoelectric conversion element 3a and the second thermoelectric conversion element 3b while enhancing both the respective Seebeck electromotive forces V1 and the Nernst electromotive forces V2. Accordingly, the efficiency of generating the thermoelectromotive force generated from the thermoelectric conversion device 2 can be further improved.

The third thermoelectric conversion element 3c is provided, for example, in place of the connecting member 24. For example, the third thermoelectric conversion element 3c is arranged at a position spaced apart from the first thermoelectric conversion element 3a in the gradient direction D1. In this case, the distance between the second connection region R2 of the first thermoelectric conversion element 3a and the second connection region R2 of the third thermoelectric conversion element 3c in the gradient direction D1 is shorter than the distance between the second connection region R2 of the first thermoelectric conversion element 3a and the first connection region R1 of the third thermoelectric conversion element 3c in the gradient direction D1. The second electrode 23 connected to the second connection region R2 of the first thermoelectric conversion element 3a extends along the gradient direction D1 and is connected to the second connection region R2 of the third thermoelectric conversion element 3c. As a result, the Seebeck electromotive forces V1 and V1′ and the Nernst electromotive forces V2 and V2′ are superimposed on each other in the same direction on the circuit, thereby making it possible to further efficiently increase the output electromotive force Vₜₒₜₐₗ.

That is, the connecting member 24 shown in FIG. 6 and FIG. 7 may be the third thermoelectric conversion element 3c. The thermoelectric conversion device 2 shown in FIG. 8 differs from the thermoelectric conversion device 2 shown in FIG. 6 and FIG. 7 in that the conductor (for example, the connecting member 24) connecting the thermoelectric conversion elements 3a and 3b is replaced with the third thermoelectric conversion element 3c, which is another thermoelectric conversion element 3. Such a third thermoelectric conversion element 3c is an element whose Seebeck coefficient has an opposite sign to that of the original thermoelectric conversion elements 3a and 3b, but whose polarity with respect to the anomalous Nernst effect is the same. Such an element can be appropriately selected. This allows for an additional voltage to be generated.

In such a thermoelectric conversion device 2, for example, one side of the substrate 21 may be connected to a high-temperature heat source, and the other side may not be connected to any heat source or connected to a lower-temperature heat source. In addition, in such a thermoelectric conversion device 2, for example, one side of the substrate 21 may be connected to a low-temperature heat source, and the other side may be connected to no heat source or to a higher-temperature heat source. That is, if an environment exists in which a temperature gradient is generated, it is possible to generate a voltage by installing such a thermoelectric conversion device 2. Furthermore, a thermoelectric conversion method using this thermoelectric conversion device 2 can also generate a voltage. In addition, a power generation system or a sensor system incorporating such a thermoelectric conversion device 2 can be configured.

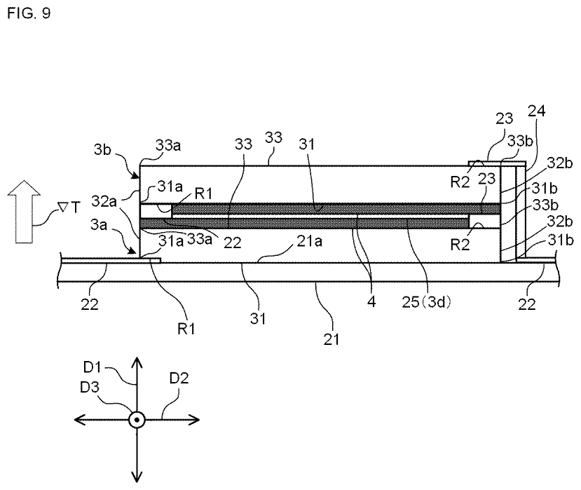

In addition, at least some of the plurality of thermoelectric conversion elements 3 may be arranged so as to be stacked in the gradient direction D1. FIG. 9 is a diagram showing an example of the thermoelectric conversion device 2 including a plurality of thermoelectric conversion elements 3. As shown in FIG. 9, the thermoelectric conversion device 2 includes a substrate 21, a plurality of thermoelectric conversion elements 3, a first electrode 22, a second electrode 23, an electrical insulation layer 4, and a connecting member 25. The first thermoelectric conversion element 3a and the second thermoelectric conversion element 3b are the same as those described above, and therefore their explanation is omitted. Here, for convenience of explanation, the thermoelectric conversion element 3 directly stacked on the substrate 21 is referred to as the first thermoelectric conversion element 3a, and the thermoelectric conversion element 3a further stacked on top of the thermoelectric conversion element 3a is referred to as the second thermoelectric conversion element 3b. Note that the first thermoelectric conversion element 3a and the second thermoelectric conversion element 3b each have Seebeck coefficients and Nernst coefficients with the same sign. The distance between the first connection region R1 of the second thermoelectric conversion element 3b and the first connection region R1 of the first thermoelectric conversion element 3a in the gradient direction D1 is shorter than the distance between the second connection region R2 of the second thermoelectric conversion element 3b and the first connection region R1 of the first thermoelectric conversion element 3a in the gradient direction D1. For example, the first connection region R1 of the second thermoelectric conversion element 3b and the first connection region R1 of the first thermoelectric conversion element 3a are configured so as to overlap each other in the gradient direction D1, whereas the second connection region R2 of the second thermoelectric conversion element 3b and the first connection region R1 of the first thermoelectric conversion element 3a are configured so as not to overlap each other in the gradient direction D1.

The first electrode 22 is connected to the first connection region R1 of each thermoelectric conversion element 3a and 3b. The second electrode 23 is connected to the second connection region R2 of each thermoelectric conversion element 3a and 3b.

As shown in FIG. 9, the electrical insulation layer 4 is arranged so as to be interposed between the first thermoelectric conversion element 3a and the second thermoelectric conversion element 3b. It is preferable that the electrical insulation layer 4 has thermal conductivity. This allows effective transmission of the heat flow based on the temperature gradient ∇T to the plurality of stacked thermoelectric conversion elements 3, thereby suppressing a reduction in the Nernst electromotive force V2 of the plurality of stacked thermoelectric conversion elements 3.

The connecting member 25 is configured to connect the second electrode 23 of the first thermoelectric conversion element 3a to the first electrode 22 of the second thermoelectric conversion element 3b stacked on the first thermoelectric conversion element 3a. The specific aspect of the connecting member 25 is not particularly limited. For example, the connecting member 25 may be arranged so as to be incorporated within the insulation layer 4.

With such a configuration, the output electromotive force Vₜₒₜₐₗ of the thermoelectric conversion device 2 per unit area of the surface defined by the longitudinal direction D2 and the width direction D3 can be increased, thereby further improving the thermoelectric conversion efficiency.

The connecting member 25 may be replaced by a fourth thermoelectric conversion element 3d. The fourth thermoelectric conversion element 3d has a Seebeck coefficient of the same sign as that of the first thermoelectric conversion element 3a or the second thermoelectric conversion element 3b, and has a Nernst coefficient of a different sign from that of the first thermoelectric conversion element 3a or the second thermoelectric conversion element 3b. With such a configuration, the output electromotive force Vₜₒₜₐₗ output from the thermoelectric conversion device 2 can be further increased, thereby further improving the thermoelectric conversion efficiency.

In addition, the thermoelectric conversion device 2 may also include a connecting member 24. The connecting member 24 may, for example, be connected to the first connection region R1 of an additional first thermoelectric conversion element 3a arranged at a different position. That is, the stacked body of the plurality of thermoelectric conversion elements 3 may, for example, be arranged two-dimensionally on the substrate 21, as in the example shown in FIG. 6. In this manner, the thermoelectric conversion device 2 may be provided with the thermoelectric conversion elements 3 in a three-dimensional arrangement.

### Others

The above-mentioned embodiments may be implemented in appropriate combination with each other. Furthermore, the above-mentioned embodiments may also be implemented in combination with the following aspects as appropriate.

The thermoelectric conversion device 2 does not need to be used as the power supply system 1, and may be applied to any system in which a temperature gradient ∇T (or a corresponding heat flow Q) is involved, for example. For example, the thermoelectric conversion device 2 may be used as a heat flow sensor.

The gradient direction D1, the longitudinal direction D2, and the width direction D3 are merely examples of the first direction, the second direction, and the third direction, respectively, and are not limited thereto. These directions may be appropriately defined depending on the direction of the temperature gradient ∇T (or the heat flow Q).

The supply object Ob may be treated as a component external to the power supply system 1.

The shape of the thermoelectric conversion element 3 may be any shape and is not limited to one extending in the longitudinal direction D2. For example, the thermoelectric conversion element 3 may be elongated in the width direction D3 or may be plate-shaped (for example, disk-shaped) extending across the placement surface 21a. Even in such shapes, it is only necessary that the first connection region R1 and the second connection region R2 be spaced apart from each other in the gradient direction D1 and also spaced apart from each other in the longitudinal direction D2.

The above-mentioned embodiments may be provided in each of the following aspects.
(1) A thermoelectric conversion device, comprising: at least one thermoelectric conversion element configured to generate a thermoelectromotive force due to a temperature gradient along a first direction, the thermoelectromotive force including: a Seebeck electromotive force generated along the first direction by a Seebeck effect based on the temperature gradient; and a Nernst electromotive force generated by an anomalous Nernst effect based on the temperature gradient so as to have a component along a second direction perpendicular to the first direction; a first electrode connected to a first connection region of the thermoelectric conversion element; and a second electrode connected to a second connection region of the thermoelectric conversion element, the first connection region and the second connection region being spaced apart in the first direction and also being spaced apart in the second direction.

With such a configuration, since the first connection region and the second connection region are spaced apart in the first direction, the first electrode and the second electrode can also output the Seebeck electromotive force generated along the first direction. Furthermore, since the first connection region and the second connection region are spaced apart in the second direction, the first electrode and the second electrode can also output the Nernst electromotive force generated along the second direction. As a result, the first electrode and the second electrode can output, as the thermoelectromotive force, an electromotive force in which the Seebeck electromotive force and the Nernst electromotive force are superimposed on each other. This makes it possible to provide a thermoelectric conversion system capable of outputting a larger electromotive force compared with the case where only one of the electromotive forces is output, for example.
(2) The thermoelectric conversion device according to (1), wherein: the thermoelectric conversion element is configured to extend along the second direction.

With such a configuration, the Nernst effect generated from the thermoelectric conversion element can be increased, thereby further increasing the thermoelectromotive force output from the thermoelectric conversion device.
(3) The thermoelectric conversion device according to (2), wherein: a length of the thermoelectric conversion element in the second direction is longer than a length of the thermoelectric conversion element in the first direction.

With such a configuration, the contribution of the Nernst electromotive force included in the thermoelectromotive force becomes greater, and thus the response speed to the generation or change of the temperature gradient in the thermoelectric conversion device can be increased.
(4) The thermoelectric conversion device according to any one of (1) to (3), wherein: the first connection region and the second connection region are each arranged at both ends of the thermoelectric conversion element in the second direction.

With such a configuration, the component of the Nernst electromotive force included in the thermoelectromotive force output from the first electrode and the second electrode can be increased.
(5) The thermoelectric conversion device according to (4), wherein: the thermoelectric conversion element includes a first surface, and a second surface positioned opposite to the first surface in the first direction, the first surface includes the first connection region, and the second surface includes the second connection region.

With such a configuration, the component of the Seebeck electromotive force included in the thermoelectromotive force output from the first electrode and the second electrode can be increased.
(6) The thermoelectric conversion device according to any one of (1) to (5), wherein: the at least one thermoelectric conversion element is a plurality of thermoelectric conversion elements that include a first thermoelectric conversion element and a second thermoelectric conversion element, the thermoelectric conversion device further includes a substrate, the substrate includes a placement surface defined by a normal direction that is along the first direction, each of the plurality of thermoelectric conversion elements is arranged on the placement surface, a distance between the first connection region of each of the plurality of thermoelectric conversion elements and the placement surface in the first direction is shorter than a distance between the second connection region of each of the plurality of thermoelectric conversion elements and the placement surface in the first direction, and the first thermoelectric conversion element and the second thermoelectric conversion element are connected in series by electrically connecting the first connection region of the first thermoelectric conversion element and the second connection region of the second thermoelectric conversion element.

With such a configuration, the thermoelectromotive force generated by the first thermoelectric conversion element and the thermoelectromotive force generated from the second thermoelectric conversion element are added together in response to the temperature gradient in the same direction, and are output from the first electrode and the second electrode, thereby further increasing the electromotive force output from the thermoelectric conversion device.
(7) The thermoelectric conversion device according to (6), wherein: the plurality of thermoelectric conversion elements further include a third thermoelectric conversion element, the third thermoelectric conversion element is arranged between the first thermoelectric conversion element and the second thermoelectric conversion element so as to be connected in series with each of the first thermoelectric conversion element and the second thermoelectric conversion element, the first connection region of the third thermoelectric conversion element is electrically connected to the second connection region of the first thermoelectric conversion element, the second connection region of the third thermoelectric conversion element is electrically connected to the first connection region of the second thermoelectric conversion element, a Nernst electromotive force of the third thermoelectric conversion element generated due to the temperature gradient is configured to be generated in the same direction as a Nernst electromotive force of the first thermoelectric conversion element generated due to the temperature gradient, and a Seebeck electromotive force of the third thermoelectric conversion element generated due to the temperature gradient is configured to be generated in an opposite direction to the Seebeck electromotive force of the first thermoelectric conversion element generated due to the temperature gradient.

With such a configuration, the third thermoelectric conversion element can be incorporated between the first thermoelectric conversion element and the second thermoelectric conversion element while enhancing both the respective Seebeck electromotive forces and the Nernst electromotive forces. Accordingly, the efficiency of generating the thermoelectromotive force generated from the thermoelectric conversion device can be further improved.
(8) A power supply system comprising: a supply object that is supplied with electric power; and a power supply part configured to supply the electric power to the supply object, the power supply part including a thermoelectric conversion device according to any one of (1) to (7), and being configured to output the electric power to the supply object based on the thermoelectromotive force output from the thermoelectric conversion device.
(9) A power supply method comprising: introducing the temperature gradient along the first direction into the thermoelectric conversion device according to any one of (1) to (7); and supplying, to a power supply object, an electric signal based on a thermoelectromotive force generated from the thermoelectric conversion device based on the temperature gradient.
(10) The power supply method according to (9), wherein the introducing includes introducing the temperature gradient by attaching the thermoelectric conversion device to the power supply object.

With such a configuration, the heat generated when supplying power to the power supply object, or the heat generated when the supply object is driven by the supplied power, can be used to introduce a temperature gradient into the thermoelectric conversion device. This makes it possible to reduce heat energy loss in the supply object.

Of course, the present disclosure is not limited to the above aspects.

Finally, various embodiments of the present disclosure have been described, but these are presented as examples and are not intended to limit the scope of the invention. Novel embodiments can be implemented in various other forms, and various omissions, replacements, and modifications can be made within the scope of the spirit of the invention. The embodiment and its modifications are included in the scope and the spirit of the invention and are included in the scope of the invention described in claims and the equivalent scope thereof.

1. A thermoelectric conversion device, comprising:
at least one thermoelectric conversion element configured to generate a thermoelectromotive force due to a temperature gradient along a first direction, the thermoelectromotive force including:
a Seebeck electromotive force generated along the first direction by a Seebeck effect based on the temperature gradient; and
a Nernst electromotive force generated by an anomalous Nernst effect based on the temperature gradient so as to have a component along a second direction perpendicular to the first direction;
a first electrode connected to a first connection region of the thermoelectric conversion element; and
a second electrode connected to a second connection region of the thermoelectric conversion element,
the first connection region and the second connection region being spaced apart in the first direction and also being spaced apart in the second direction.

2. The thermoelectric conversion device according to claim 1, wherein:
the thermoelectric conversion element is configured to extend along the second direction.

3. The thermoelectric conversion device according to claim 2, wherein:
a length of the thermoelectric conversion element in the second direction is longer than a length of the thermoelectric conversion element in the first direction.

4. The thermoelectric conversion device according to claim 1, wherein:
the first connection region and the second connection region are each arranged at both ends of the thermoelectric conversion element in the second direction.

5. The thermoelectric conversion device according to claim 4, wherein:
the thermoelectric conversion element includes a first surface, and a second surface positioned opposite to the first surface in the first direction,
the first surface includes the first connection region, and
the second surface includes the second connection region.

6. The thermoelectric conversion device according to claim 1, wherein:
the at least one thermoelectric conversion element is a plurality of thermoelectric conversion elements that include a first thermoelectric conversion element and a second thermoelectric conversion element,
the thermoelectric conversion device further includes a substrate,
the substrate includes a placement surface defined by a normal direction that is along the first direction,
each of the plurality of thermoelectric conversion elements is arranged on the placement surface,
a distance between the first connection region of each of the plurality of thermoelectric conversion elements and the placement surface in the first direction is shorter than a distance between the second connection region of each of the plurality of thermoelectric conversion elements and the placement surface in the first direction, and
the first thermoelectric conversion element and the second thermoelectric conversion element are connected in series by electrically connecting the first connection region of the first thermoelectric conversion element and the second connection region of the second thermoelectric conversion element.

7. The thermoelectric conversion device according to claim 6, wherein:
the plurality of thermoelectric conversion elements further include a third thermoelectric conversion element,
the third thermoelectric conversion element is arranged between the first thermoelectric conversion element and the second thermoelectric conversion element so as to be connected in series with each of the first thermoelectric conversion element and the second thermoelectric conversion element,
the first connection region of the third thermoelectric conversion element is electrically connected to the second connection region of the first thermoelectric conversion element,
the second connection region of the third thermoelectric conversion element is electrically connected to the first connection region of the second thermoelectric conversion element,
a Nernst electromotive force of the third thermoelectric conversion element generated due to the temperature gradient is configured to be generated in the same direction as a Nernst electromotive force of the first thermoelectric conversion element generated due to the temperature gradient, and
a Seebeck electromotive force of the third thermoelectric conversion element generated due to the temperature gradient is configured to be generated in an opposite direction to the Seebeck electromotive force of the first thermoelectric conversion element generated due to the temperature gradient.

8. A power supply system comprising:
a supply object that is supplied with electric power; and
a power supply part configured to supply the electric power to the supply object,
the power supply part including a thermoelectric conversion device according to claim 1, and being configured to output the electric power to the supply object based on the thermoelectromotive force output from the thermoelectric conversion device.

9. A power supply method comprising:
introducing the temperature gradient along the first direction into the thermoelectric conversion device according to claim 1; and
supplying, to a power supply object, an electric signal based on a thermoelectromotive force generated from the thermoelectric conversion device based on the temperature gradient.

10. The power supply method according to claim 9, wherein
the introducing includes introducing the temperature gradient by attaching the thermoelectric conversion device to the power supply object.
